(19) United States
(12) Patent Application Publication
(10) Pub. No.: US 2021/0018965 A1
(43) Pub. Date: Jan. 21, 2021

(54) ELECTRONIC APPARATUS

(71) Applicant: LENOVO (SINGAPORE) PTE. LTD., Singapore (SG)

(72) Inventors: Ryota Watanabe, YOKOHAMA (JP); Yasumichi Tsukamoto, YOKOHAMA (JP); Masayuki Amano, YOKOHAMA (JP)

(73) Assignee: LENOVO (SINGAPORE) PTE. LTD., Singapore (SG)

(21) Appl. No.: 16/600,246

(22) Filed: Oct. 11, 2019

(30) Foreign Application Priority Data
Jul. 17, 2019 (JP) 2019131630

(51) Int. Cl. G06F 1/20; H05K 7/20

(52) U.S. Cl. CPC G06F 1/203; H05K 7/20381; H05K 7/20972; H05K 7/20336; G06F 1/206

(57) ABSTRACT

An electronic apparatus includes: a cooling fan having a radiating fin; a system chassis that houses the cooling fan, and is provided with an air outlet on an extension of the radiating fin; a display chassis openably and closably coupled to the system chassis through a hinge; and a temperature sensor housed in the back of, of a bezel of the display chassis, an air outlet facing portion that faces the air outlet at least when the display chassis is open with respect to the system chassis.

### FIELD OF THE INVENTION

The present invention relates to an electronic apparatus.

### BACKGROUND OF THE INVENTION

An electronic apparatus, for example, a portable laptop personal computer includes a cooling fan that discharges heat radiating from electronic components in a system chassis to the outside from an air outlet of the system chassis (see, for example, Japanese Unexamined Patent Application Publication No. 2011-227925).

### SUMMARY OF THE INVENTION

A display chassis is coupled to a system chassis through a hinge. Depending on the layout of an air outlet of the system chassis, the display chassis may be affected by heat discharged from the air outlet.

The present invention has been made in view of the above-described problem, and is intended to provide an electronic apparatus capable of performing temperature control of a display chassis affected by heat discharged from an air outlet of a system chassis.

To solve the above-described problem, an electronic apparatus according to an aspect of the present invention adopts a configuration in which the electronic apparatus includes: a cooling fan having a radiating fin; a system chassis that houses the cooling fan, and is provided with an air outlet on an extension of the radiating fin; a display chassis openably and closably coupled to the system chassis through a hinge; and a temperature sensor housed in the back of, of a bezel of the display chassis, an air outlet facing portion that faces the air outlet at least when the display chassis is open with respect to the system chassis.

Furthermore, in the electronic apparatus, the air outlet may be provided on a side surface of the system chassis closest to the display chassis when the display chassis is open.

Moreover, in the electronic apparatus, the air outlet facing portion may be formed of a heat-conducting member having higher thermal conductivity than a formation material of the display chassis.

Furthermore, in the electronic apparatus, the temperature sensor may be mounted on a display substrate or a touch panel substrate housed in the display chassis.

Moreover, the electronic apparatus may further include a control device that controls operation mode of the system chassis on the basis of output data from the temperature sensor.

Furthermore, the electronic apparatus may further include a system-side temperature sensor housed in the system chassis, and the control device may control the operation mode of the system chassis further on the basis of output data from the system-side temperature sensor.

Moreover, the electronic apparatus may include a plurality of the cooling fans, and the air outlet, the air outlet facing portion, and the temperature sensor may be provided for each of the cooling fans.

The above-described aspect of the present invention can perform temperature control of the display chassis affected by heat discharged from the air outlet of the system chassis.

### BRIEF DESCRIPTION OF THE DRAWINGS

FIG. 1 is a configuration diagram of an electronic apparatus according to a first embodiment of the present invention.

FIG. 2 is a right side view of the electronic apparatus according to the first embodiment of the present invention.

FIG. 3 is a cross-sectional view on arrow A-A shown in FIG. 1.

FIG. 4 is a flowchart showing an example of the flow of control by a control device according to the first embodiment of the present invention.

FIG. 5 is a configuration diagram of an electronic apparatus according to a second embodiment of the present invention.

### DETAILED DESCRIPTION OF THE INVENTION

Embodiments of the present invention will be described below with reference to drawings.

### First Embodiment

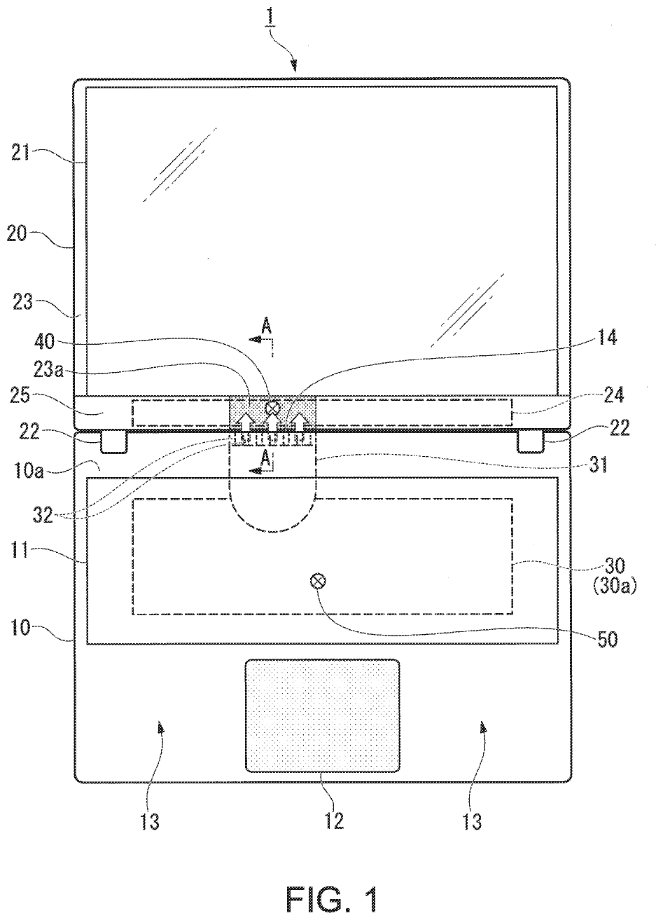

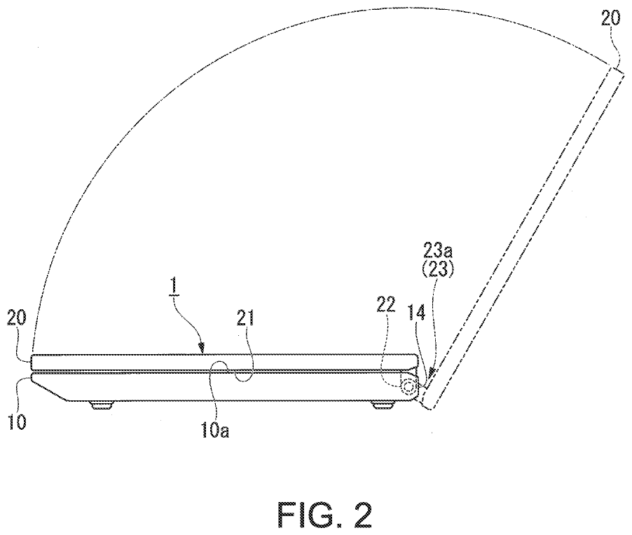

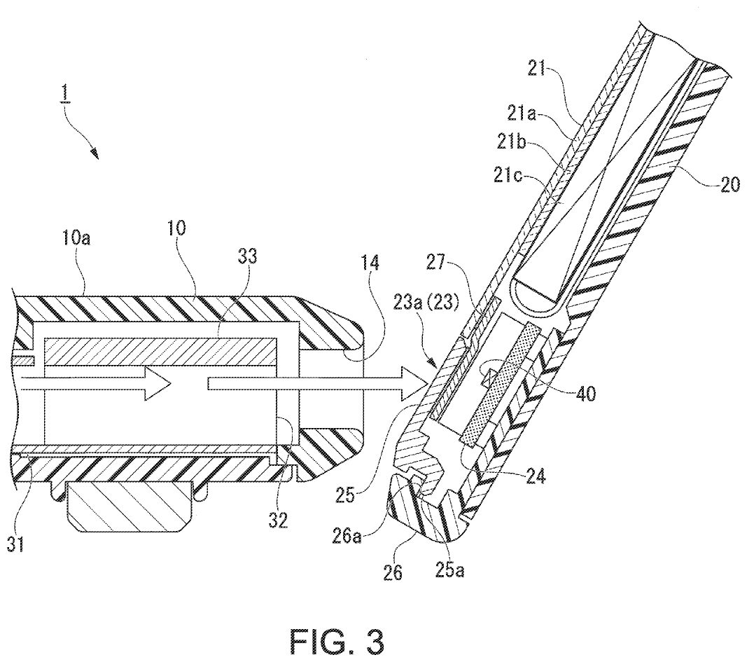

FIG. 1 is a configuration diagram of an electronic apparatus 1 according to a first embodiment of the present invention. FIG. 2 is a right side view of the electronic apparatus 1 according to the first embodiment of the present invention. FIG. 3 is a cross-sectional view on arrow A-A shown in FIG. 1.

The electronic apparatus 1 includes a system chassis 10 and a display chassis 20. This electronic apparatus 1 is a clamshell laptop personal computer (a so-called notebook personal computer).

The system chassis 10 is formed into a flattened box-like shape. On a top surface 10a of the system chassis 10, a keyboard 11 and a touch pad 12 are provided. The keyboard 11 is disposed on the back side of the top surface 10a, and the touch pad 12 is disposed on the front side of the top surface 10a. Furthermore, palm rests 13 are provided on both the right and left of the touch pad 12 on the top surface 10a.

The display chassis 20 is also formed into a flattened box-like shape, and includes a display device 21 on its surface facing the top surface 10a of the system chassis 10. As shown in FIG. 3, the display device 21 includes a cover glass 21a, a transparent electrode film 21b for a touch panel, and a display module 21c.

The display module 21c includes, for example, a light source such as an LED, a liquid crystal driving circuit, etc. The transparent electrode film 21b is attached to a back surface of the cover glass 21a, and is in contact with a front surface (a display surface) of the display module 21c. It is to be noted that the display device 21 may be formed of not a liquid crystal display but an organic EL display or the like.

As shown in FIG. 1, the bottom end of the display chassis 20 is coupled to the back side of the system chassis 10 through a pair of right and left hinges 22 spaced apart from each other so that the display chassis 20 can rotate around a shaft extending in a right-left direction. When the display chassis 20 is open as indicated by an alternate long and two short dashes line in FIG. 2, the top surface 10a of the system chassis 10 is in an open state. On the other hand, when the display chassis 20 is closed as indicated by a solid line in FIG. 2, the display chassis 20 serves as a cover that covers the display device 21 and the top surface 10a of the system chassis 10.

As shown in FIG. 1, a system board 30 (a motherboard), a cooling fan 31, etc. are housed in the system chassis 10. The system board 30 is screwed to a plurality of bosses (not shown) provided on the system chassis 10, and is disposed facing and substantially parallel to the bottom of the system chassis 10 at a distance. This system board 30 is disposed on the side of a back surface of the keyboard 11.

The cooling fan 31 includes a plurality of radiating fins 32. The plurality of radiating fins 32 is thermally connected to one end of a heat pipe 33 shown in FIG. 3. The other end (not shown) of the heat pipe 33 is thermally in contact with a heat-generating component such as a CPU (not shown) of the system board 30. The cooling fan 31 is laid out on the back side of the system chassis 10, and discharges heat from an air outlet 14 provided on a back surface (a back-side side surface) of the system chassis 10 through the radiating fins 32. That is, the air outlet 14 is provided on the side surface of the system chassis 10 closest to the display chassis 20 when the display chassis 20 is open.

As shown in FIG. 1, the air outlet 14 of the system chassis 10 is provided on an extension of the radiating fins 32. It is to be noted that an air outlet (a dummy air outlet) may be provided on a portion other than the extension of the radiating fins 32 to make it appear as if an air outlet is provided over the entire back surface of the system chassis 10 for a reason of a design. However, “the air outlet 14” in the present application means an air outlet through which exhaust air from the cooling fan 31 is actually discharged.

In a bezel 23 (a frame part) of the display chassis 20 surrounding the periphery of the display device 21, a display substrate 24, a temperature sensor 40, etc. are housed. The display substrate 24 is electrically connected to the above-described display module 21c. Furthermore, the display substrate 24 is also electrically connected to the system board 30 in the system chassis 10 via a cable or the like (not shown) running through the hinges 22.

As shown in FIG. 2, a portion of the bezel 23 of the display chassis 20 faces the air outlet 14 at least when the display chassis 20 is open with respect to the system chassis 10. This portion is a portion onto which the exhaust air from the cooling fan 31 is blown, and is hereinafter referred to as an air outlet facing portion 23a. It is to be noted that in FIG. 1, the air outlet facing portion 23a is indicated by a dot pattern.

As shown in FIG. 3, the temperature sensor 40 is disposed on the back of the air outlet facing portion 23a. The temperature sensor 40 is, for example, a semiconductor sensor such as a diode sensor. The temperature sensor 40 is mounted on the display substrate 24. It is to be noted that if the internal space of the display chassis 20 allows, the temperature sensor 40 may be mounted on a dedicated substrate.

The air outlet facing portion 23a is formed of a heat-conducting member 25 having higher thermal conductivity than a formation material of the display chassis 20. The formation material of the display chassis 20 includes, for example, a resin material such as epoxy resin, polycarbonate resin, or fiber reinforced plastics of these. The heat-conducting member 25 includes, for example, a metallic material such as aluminum, aluminum alloy, magnesium, or magnesium alloy. That is, a portion of the bezel 23 is made of the metallic material.

The heat-conducting member 25 has an engagement projection 25a engaged with a side frame 26 (made of the above-described resin material) of the display chassis 20. The side frame 26 has an engagement groove 26a into which the engagement projection 25a is undercut-fitted. The heat-conducting member 25 extends along one side of the bottom end of the above-described cover glass 21a, and is connected to the one side of the cover glass 21a through a connecting member 27. The connecting member 27 connects a back surface of the top end of the heat-conducting member 25 and a back surface of the bottom end of the cover glass 21a.

To return to FIG. 1, the electronic apparatus 1 includes a control device 30a that controls the operation mode of the system chassis 10 on the basis of output data from the temperature sensor 40. The control device 30a is composed of various electronic components including, for example, the CPU mounted on the system board 30. Also on the system board 30, a temperature sensor 50 that measures the temperature of the system side is mounted. The control device 30a controls the operation mode of the system chassis 10 further on the basis of output data from the system-side temperature sensor 50.

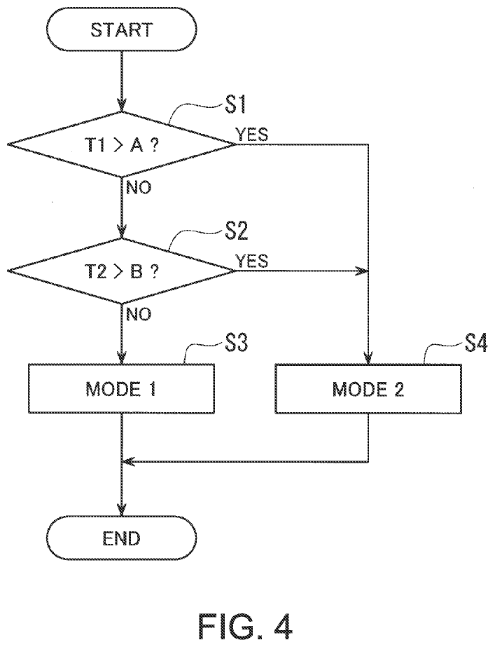

FIG. 4 is a flowchart showing an example of the flow of control by the control device 30a according to the first embodiment of the present invention.

First, the control device 30a determines whether or not output data (a temperature T1) from the display-side temperature sensor 40 is higher than a preset threshold A (Step S1).

In a case where the temperature T1 is equal to or lower than the threshold A (“NO” at Step S1), the control device 30a next determines whether or not output data (a temperature T2) from the system-side temperature sensor 50 is higher than a preset threshold B (Step S2).

In a case where the temperature T2 is equal to or lower than the threshold B (“NO” at Step S2), the temperatures of the display side and the system side are both equal to or lower than respective set values, and thus the control device 30a causes the system side to operate in normal operation mode (MODE 1) without lowering the CPU performance (Step S3).

On the other hand, in a case where a result of the determination at Step S1 or S2 is “YES”, the temperature of the display side or the system side exceeds or is likely to exceed the set value, and thus the control device 30a switches the operation mode to power-saving operation mode (MODE 2) in which, for example, the CPU performance is lowered (Step S4).

This reduces the temperature of the CPU, and therefore the temperature of exhaust air blown onto the air outlet facing portion 23a of the bezel 23 through the heat pipe 33, the radiating fins 32, and the air outlet 14 can be reduced. Alternatively, at Step S4 (in MODE 2), instead of lowering the CPU performance, the rotation speed of the cooling fan 31 may be increased, thereby keeping the CPU performance while maintaining the surface temperature of the air outlet facing portion 23a at a comfortable level.

In this way, it is possible to perform temperature control so as to avoid the surface temperature of the air outlet facing portion 23a exceeding the set value.

As above, the electronic apparatus 1 according to the present embodiment adopts a configuration in which it includes the cooling fan 31 having the radiating fins 32, the system chassis 10 that houses the cooling fan 31 and is provided with the air outlet 14 on the extension of the radiating fins 32, the display chassis 20 openably and closably coupled to the system chassis 10 through the hinges 22, and the temperature sensor 40 housed in the back of, of the bezel 23 of the display chassis 20, the air outlet facing portion 23a that faces the air outlet 14 at least when the display chassis 20 is open with respect to the system chassis 10, and therefore can perform temperature control of the display chassis 20 affected by heat discharged from the air outlet 14 of the system chassis 10.

Furthermore, as in the present embodiment, even though the electronic apparatus 1 has a layout in which the air outlet 14 is provided on the side surface of the system chassis 10 closest to the display chassis 20 when the display chassis 20 is open, and thus the display chassis 20 is likely to be affected by heat, it is possible to effectively perform the temperature control of the display chassis 20.

Moreover, in the present embodiment, the air outlet facing portion 23a is formed of the heat-conducting member 25 having higher thermal conductivity than the formation material of the display chassis 20; therefore, it is possible to enhance the feedback response performance of the temperature sensor 40.

Furthermore, in the present embodiment, the temperature sensor 40 is mounted on the display substrate 24 housed in the display chassis 20; therefore, it is not necessary to provide a dedicated substrate for the temperature sensor 40, and it is possible to contribute to saving the internal space of the display chassis 20.

Moreover, in the present embodiment, the electronic apparatus 1 includes the control device 30a that controls the operation mode of the system chassis 10 on the basis of output data from the temperature sensor 40, and therefore can perform temperature control so as to avoid the surface temperature of the air outlet facing portion 23a exceeding the set value.

Furthermore, in the present embodiment, the electronic apparatus 1 includes the system-side temperature sensor 50 housed in the system chassis 10, and the control device 30a controls the operation mode of the system chassis 10 further on the basis of output data from the system-side temperature sensor 50; therefore, the performance of the system side can be controlled on the more secure side.

### Second Embodiment

Subsequently, a second embodiment of the present invention is described. In the following description, the same or similar component to that of the first embodiment is assigned the same reference numeral, and its description is made briefly or omitted.

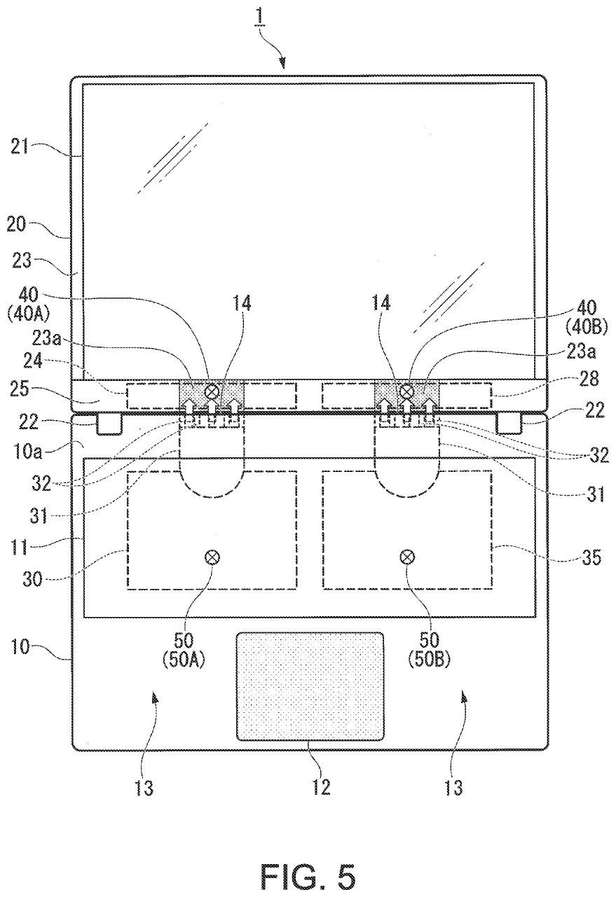

FIG. 5 is a configuration diagram of the electronic apparatus 1 according to the second embodiment of the present invention.

As shown in FIG. 5, the electronic apparatus 1 according to the second embodiment differs from that of the first embodiment in that the electronic apparatus 1 includes a plurality of the cooling fans 31, and the air outlet 14, the air outlet facing portion 23a, and the temperature sensors 40 and 50 are provided for each of the cooling fans 31.

In the system chassis 10, besides the above-described system board 30, a second system board 35 (a graphics board) with a GPU, etc. mounted thereon is housed. One cooling fan 31 is provided for each of the system board 30 and the second system board 35. It is to be noted that heat generated in the GPU of the second system board 35 is transferred to the radiating fins 32 on the side of the second system board 35 through a heat pipe (not shown), and is discharged from the back surface of the system chassis 10 through the air outlet 14.

Furthermore, in the display chassis 20, besides the display substrate 24, a touch panel substrate 28 electrically connected to the above-described transparent electrode film 21b is housed. Also on the touch panel substrate 28, the temperature sensor 40 (40B) is mounted. The temperature sensor 40B is disposed on the back of the air outlet facing portion 23a that faces the air outlet 14 on the side of the second system board 35. Moreover, also on the second system board 35, the temperature sensor 50 (50B) is mounted.

According to the above-described configuration of the second embodiment, by means of the temperature sensor 40 (40A) and the temperature sensor 50 (50A), the CPU performance can be controlled, and temperature control of the air outlet facing portion 23a on the side of the system board 30 can be performed, just like the first embodiment. Furthermore, by means of the temperature sensor 40 (40B) and the temperature sensor 50 (50B), the GPU performance can be controlled, and temperature control of the air outlet facing portion 23a on the side of the second system board 35 can also be performed.

The embodiments of the present invention are described in detail above with reference to the drawings; however, a specific configuration is not limited to the foregoing embodiments, and a design, etc. may be modified without departing from the scope of the invention. The configurations described in the foregoing embodiments can be combined arbitrarily as long as it does not contradict the nature of the invention.

For example, in the foregoing embodiments, a laptop personal computer is described as an example of the electronic apparatus; however, the present invention is not limited to this, and can be applied to other electronic apparatuses such as a clamshell tablet as well.

1. An electronic apparatus comprising:
a cooling fan having a radiating fin;
a system chassis that houses the cooling fan, and is provided with an air outlet on an extension of the radiating fin;
a display chassis openably and closably coupled to the system chassis through a hinge; and
a temperature sensor housed in a bezel of the display chassis, wherein the temperature sensor is in temperature communication with an air outlet facing portion of the bezel that faces the air outlet at least when the display chassis is open with respect to the system chassis.

2. The electronic apparatus according to claim 1, wherein the air outlet is on a side surface of the system chassis and closest to the display chassis when the display chassis is open.

3. The electronic apparatus according to claim 1, wherein the air outlet facing portion is formed of a heat-conducting member having higher thermal conductivity than a formation material of the display chassis.

4. The electronic apparatus according to claim 1, wherein the temperature sensor is mounted on a display substrate or on a touch panel substrate housed in the display chassis.

5. The electronic apparatus according to claim 1, further comprising a control device that controls an operation mode of the system chassis on a basis of output data from the temperature sensor.

6. The electronic apparatus according to claim 5, further comprising a system-side temperature sensor housed in the system chassis,
wherein the control device further controls the operation mode of the system chassis on a basis of output data from the system-side temperature sensor.

7. The electronic apparatus according to claim 1, further comprising a plurality of the cooling fans,
wherein a respective air outlet, a respective air outlet facing portion, and a respective temperature sensor are provided for each of the cooling fans.
